(19) United States
(12) Patent Application Publication
(10) Pub. No.: US 2009/0146773 A1
(43) Pub. Date: Jun. 11, 2009

(54) LATERAL SNAP ACTING MEMS MICRO SWITCH

(75) Inventor: Joon Won Kang, Redmond, WA (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc.

(21) Appl. No.: 11/952,794

(22) Filed: Dec. 7, 2007

(51) Int. Cl. H01H 61/00; H01L 21/00

(52) U.S. Cl. 337/123; 438/52; 257/E21.001

(57) ABSTRACT

A MEMS micro-switch with a lateral snap action includes a laterally bowed beam and an electro thermal actuator. The electro thermal actuator can be activated in response to the application of an actuation voltage and a push rod pushes the laterally bowed beam to a transition point through a push-pull connector. The bowed beam can be snapped to an opposite position at the transition point and a moving electrode makes strong contact to fixed electrodes, which makes the switch turn on with strong contact force. The actuator can be deactivated and the push rod pulls the bowed beam back to the transition point and snapped back to an original position, which makes the switch turn off. The switch can be fabricated utilizing glass and SOI wafer bonding technique.

### TECHNICAL FIELD

Embodiments are generally related to MEMS (Micro-electromechanical Systems) devices and methods. Embodiments are also related to micro-switches.

### BACKGROUND OF THE INVENTION

MEMS (Microelectromechanical Systems) include mechanical and electrical components having dimensions in the order of microns or smaller. MEMS structures are utilized in numerous applications including switches, actuators, valves and sensors. MEMS devices are extremely small machines that can be fabricated utilizing integrated circuit techniques or the like. The small size of MEMS devices allows production of high speed, low-power and high reliability mechanisms. Microelectromechanical switches can be utilized in modern electronic devices because of their potential for allowing integration of high-quality switches with circuits formed utilizing IC (Integrated Circuit) technology. MEMS switches can control electrical, mechanical, or optical signal flow.

A MEMS micro switch is an electric switch that can be actuated by very little physical force and is commonly utilized due to its low-cost and extreme durability. The defining feature of the micro switch is that a relatively small movement at an actuator button produces a relative large movement at the electrical contacts, which occurs at a high speed. The most common micro switch mechanism is based on electro-thermal actuation, which provides the motion needed in such devices.

One problem associated with the majority of prior art micro switches is that the switching and releasing forces are not enough to provide a clear “on” and “off” action. That is, micro-electromechanical contact switches include electrodes that tend to stick to one another upon contact, making it difficult to separate them in order to turn the switch off. This results in a delayed “off” action or prolonged arcing and in a worst case, continuous on and off vibrations of the contact which can cause serious damage to the contact switch.

FIG. 1 illustrates a schematic view of a prior art MEMS micro-switch 100. The prior art MEMS micro-switch 100 depicted in FIG. 1 generally includes an electro-thermal actuator 110 and an electrical contact 140 associated with an anchored electrode 150, a moving rod 120 and a movable electrode 130. An actuation voltage can be applied to the electro-thermal actuator 110. The electro-thermal actuator 110 becomes “hot” and the moving rod 120 pushes the moving electrode 130 toward the anchored electrodes 150. The moving electrode 130 makes electrical contact with the anchored electrode 150 and the switch 100 can be turned on or in an active state. The switch 100 can be turned off when the actuating current is cut off. The current that is applied to and removed from the electro-thermal actuator 110 results in the moving electrode 130 and the anchored electrodes 150 adhering to each other. The lack of a switching force at the contacts of the moving electrode 130 and the anchored electrodes 150 prevents the proper switching control of the micro switch 100.

Based on the foregoing it is believed that a need exists for an improved MEMS micro switch with a lateral snap action for increasing the switching force as disclosed in further detail herein.

### BRIEF SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the present invention to provide for an improved MEMS structure for micro switches.

It is another aspect of the present invention to provide for an improved MEMS micro switch with lateral snap action.

The aforementioned aspects and other objectives and advantages can now be achieved as described herein. A MEMS micro switch with a lateral snap action includes a laterally bowed beam and an electro thermal actuator. The electro thermal actuator can be activated in response to an application of actuation current and a push rod pushes the bowed beam to a transition position through a push-pull connector. The bowed beam can be snapped to an opposite position at the transition point and a moving electrode makes strong electrical contact to fixed electrodes, which makes the switch turn on with strong contact force. The actuator can be deactivated and the push rod pulls the bowed beam back to the transition point and snapped back to an original position, which makes the switch turn off. The MEMS micro switch can be fabricated utilizing glass and SOI (silicon on insulator) wafer bonding technique.

The glass wafer can be etched to form a cavity utilizing patterned masking layer, which can provide a final support substrate for moving parts associated with the MEMS micro switch. The SOI wafer can be etched to form device structures utilizing a silicon DRIE (Deep reactive-ion etching) process and patterned masking layer. The glass wafer and the SOI wafer can be bonded utilizing anodic bonding and a handle layer associated with the SOI wafer can be removed by wet etch, plasma etch and other grinding methods. A metallic structure can be deposited on a device layer of the SOI wafer for the fixed electrode, movable electrode and pads.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1 illustrates a schematic view of a prior art MEMS micro switch;

FIG. 2 illustrates a schematic view of a lateral bowed beam showing snap action, which can be implemented in accordance with a preferred embodiment;

FIG. 3 illustrates a schematic view of a MEMS micro switch with the lateral bowed beam before snap action, which can be implemented in accordance with a preferred embodiment;

FIG. 4 illustrates a schematic view of the MEMS micro switch with the lateral bowed beam after snap action, which can be implemented in accordance with a preferred embodiment;

FIG. 5A-5C illustrates cross sectional views of a base glass wafer during progressive steps of a fabrication process for the MEMS micro switch, which can be implemented in accordance with a preferred embodiment;

FIG. 6A-6C illustrates cross sectional views of an SOI wafer during progressive steps of a fabrication process for the MEMS micro switch, which can be implemented in accordance with a preferred embodiment;

FIG. 7A illustrates a cross sectional view of the SOI part fusion bonded onto the top surface of the glass part for the MEMS micro switch, which can be implemented in accordance with a preferred embodiment;

FIG. 7B illustrates a cross sectional view of the SOI part fusion bonded onto the top surface of the glass part after removal of the SOI wafer's handle layer for the MEMS micro switch, which can be implemented in accordance with a preferred embodiment;

FIG. 7C illustrates a cross sectional view of the SOI part fusion bonded onto the top surface of the glass part with metallic structures for the MEMS micro switch, which can be implemented in accordance with a preferred embodiment;

FIG. 8 illustrates another cross sectional view of the SOI part fusion bonded onto the top surface of the glass part after deposition of metallic structures for the MEMS micro switch, which can be implemented in accordance with a preferred embodiment; and

FIG. 9 illustrates a detailed flow chart of operations illustrating logical operational steps of a method for operating the MEMS micro switch with snap action, which can be implemented in accordance with an alternative embodiment;

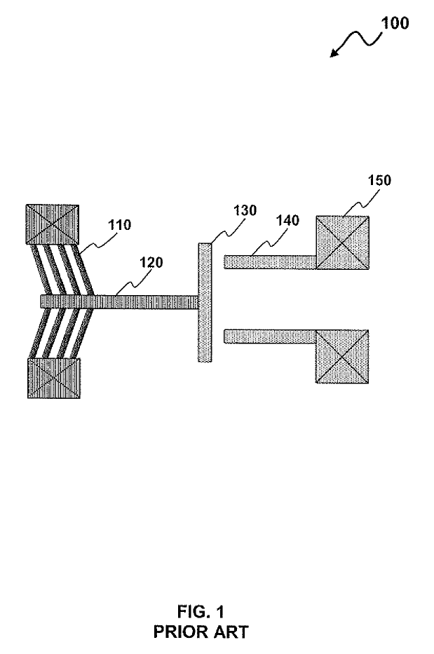

### DETAILED DESCRIPTION

The particular values and configurations discussed in these non-limiting examples can be varied and are cited merely to illustrate at least one embodiment and are not intended to limit the scope thereof.

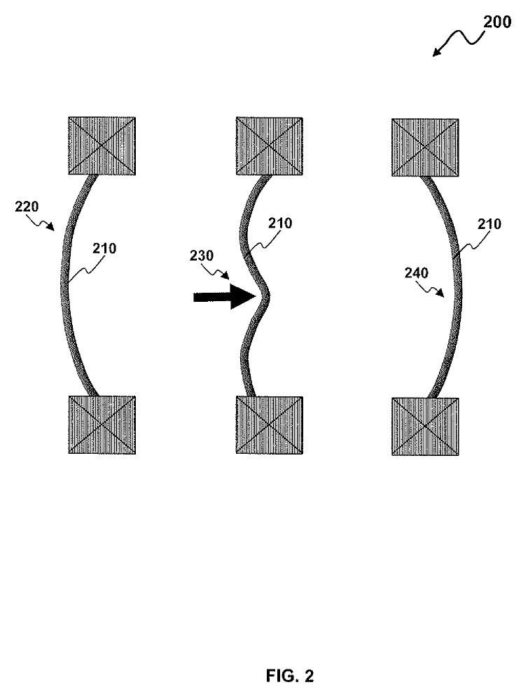

Referring to FIG. 2, a schematic view of a lateral bowed beam showing snap action 200 is illustrated, which can be implemented in accordance with a preferred embodiment. As indicated in FIG. 2, the lateral bowed beam 210 can be in an initial stage as indicated by arrow 220. A force can be applied to the lateral bowed beam 210 and the beam 210 can be transited to an intermediate stage 230. If the applied force exceeds a transition point, a snap action occurs and the lateral bowed beam 210 can be stabilized at a second stage as indicated by arrow 240.

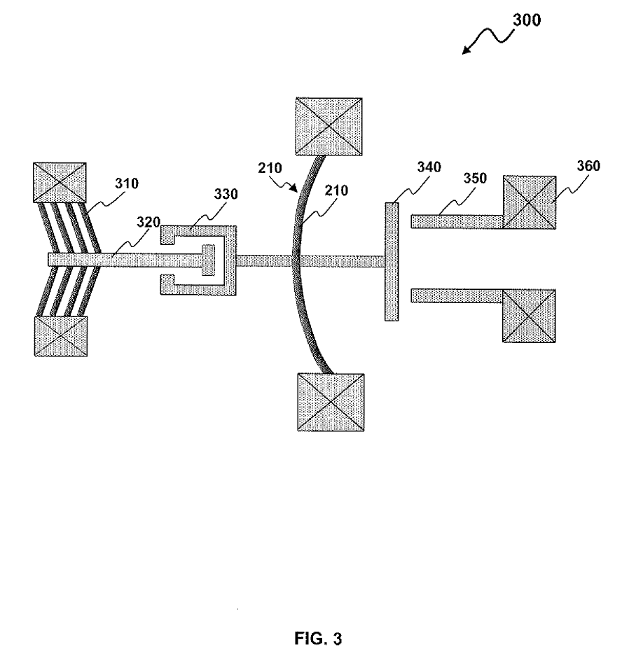

Referring to FIG. 3, a schematic view of a MEMS micro switch 300 with the lateral bowed beam 210 before a snap action is illustrated, in accordance with a preferred embodiment. The MEMS micro switch 300 includes an actuator 310, a push-pull connector 330, a bowed beam 210, a fixed electrode 360 and a movable electrode 340. FIG. 3 illustrates a general overview of a MEMS micro switch 300 in an “open” position. An electrical contact 350 can be connected to the fixed electrodes 360 on one end and can be aligned and adapted to mate with the movable electrode 340.

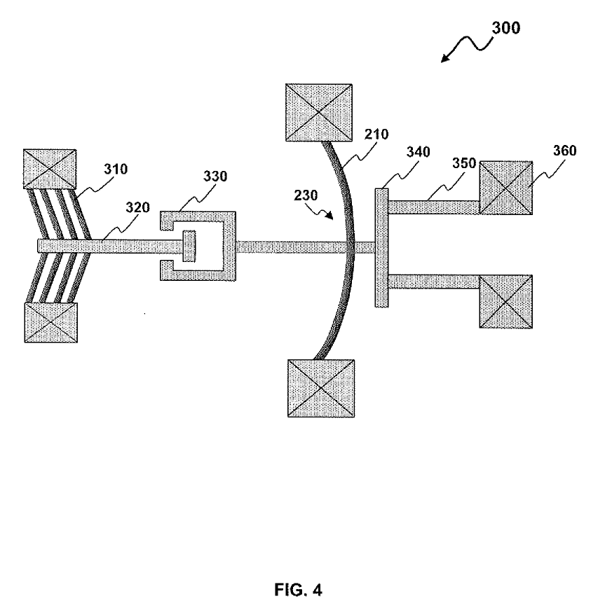

Referring to FIG. 4, a schematic view of the MEMS micro switch 300 of FIG. 3 with the lateral bowed beam 210 after a snap action is illustrated, in accordance with a preferred embodiment. The electro-thermal actuator 310 can be activated by an actuation current. The push rod 320 pushes the bowed beam 210 to the transition position as depicted in FIG. 2 through a push-pull connector 330. At the transition position, the bowed beam 210 is snapped to the opposite position and the moving electrode 340 makes a strong contact with the anchored electrode 360 through the electrical contact 350.

Such a configuration results in the switch 300 turned to an “on” condition or to an active state. When the actuator 310 is deactivated, the push rod 320 pulls the bowed beam 210 back to the transition position through push-pull connector 330. Then, the bowed beam 210 snaps back to its original position as depicted in FIG. 2, which results in the switch transitioning to an “off” condition. As the temperature of the electro-thermal actuator 310 attains its predetermined set-point temperature of operation, the bowed beam 210 moves with a snap-action to an opposite position. As the temperature of the electro-thermal actuator 310 is reduced from the high temperature toward a predetermined set-point temperature of operation, the bowed beam 210 shrinks much more rapidly and snaps back to the original position. Note that the push rod 320 can push or pull the bowed beam 210 through the push-pull connector 330 even though they are physically separated. Because they are physically separated, the snap action of the bowed beam will not affect the push rod 320 and electro-thermal actuator 310 during both the “ON” or “OFF” operations.

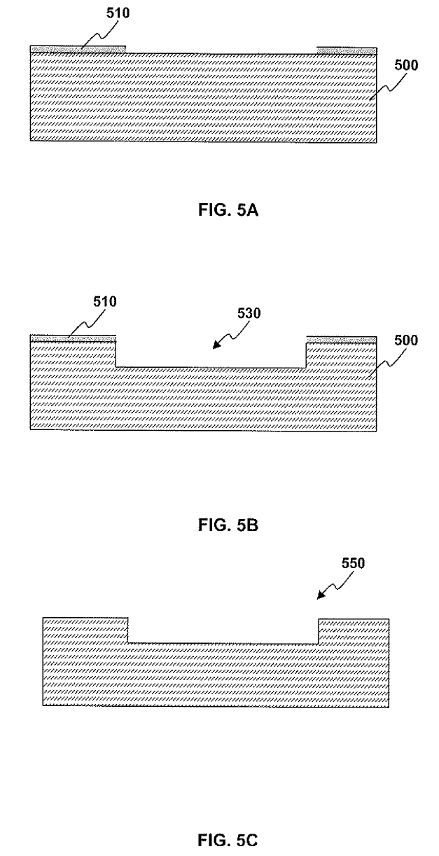

Referring to FIG. 5A-5C, cross sectional views of a base glass wafer 500 during progressive steps of a fabrication process for the MEMS micro switch 300 are illustrated, in accordance with a preferred embodiment. As depicted in FIGS. 5A-5C, a masking layer 510 can be deposited on the glass wafer 500 and the masking layer 510 patterned, as illustrated in FIG. 5A. The thickness, however, of the base wafer 500 can vary greatly and still be usable for fabrication of the MEMS switch 300. The glass wafer 500 can be etched to create a cavity 530, as illustrated in FIG. 5B. The masking layer 510 can then be removed in order to form a complete glass part 550, as depicted in FIG. 5C. The glass part 550 can be utilized as a final support substrate and the cavity 530 utilized as a cavity for moving parts for the MEMS switch 300.

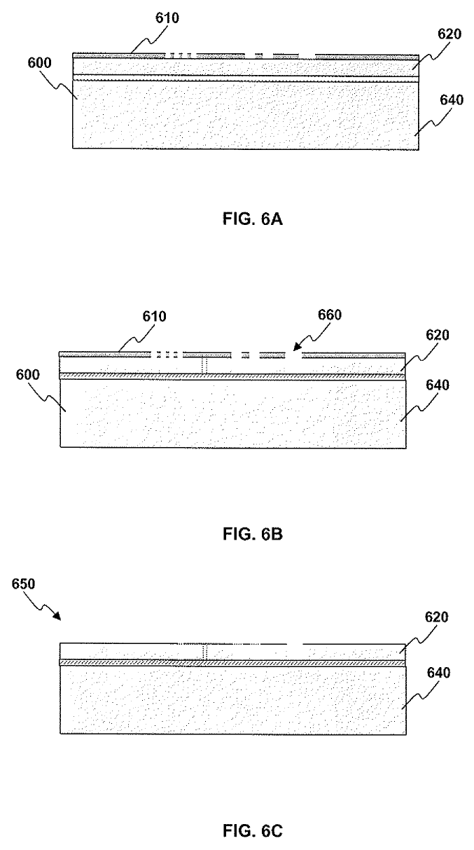

Referring to FIG. 6A-6C, cross sectional views of an SOI wafer 600 during progressive steps of a fabrication process for the MEMS micro switch 300 is illustrated, in accordance with a preferred embodiment. The MEMS switch 300 can be made in accordance with various known fabrication processes. The MEMS switch, however, can be constructed on a commercially available silicon-on-insulator (SOI) wafer. Such an SOI wafer can include a single-crystal base and, for example, approximately 2 microns of thermally grown silicon oxide between the base and approximately 5-50 microns of single-crystal silicon overlying the silicon oxide. Although the SOI wafer can be configured according to a standard wafer bonding process, it can be understood that such an SOI wafer is described herein for illustrative and exemplary purposes only, and can be configured according to other fabrication processes or in association with other layer types or thicknesses.

The SOI wafer 600 generally includes a handle layer 640 and a device layer 620. A masking layer 610 can be deposited on the device layer 620 of the SOI wafer 600 and the masking layer 610 patterned as shown in FIG. 6A. The device layer 620 can be etched in order to mask device structures for the MEMS micro switch 300 as illustrated in FIG. 3. The silicon device layer 620 can be preferably etched utilizing standard silicon etching procedures, such as a DRIE (Deep Reactive Ion Etch) process. Preferably, a standard photolithography process can be utilized to define the desired structural shapes in the SOI wafer 600. Examples of suitable shapes include, but are not limited to, cantilevered beams, suspended beams, combs, tuning forks, plates, etc.

One or more trenches such as trench 660 can be formed on the device layer 620 in order to form device structures such as, for example, actuators, push-pull connectors, bowed beams metallic electrodes, and so forth. The depth of such trenches can be, for example, approximately 5-50 microns deep to the internal oxide. A plasma system, such as for example, an RIE (Reactive Ion Etch) can provide for good uniformity and anisotropy, and can be further utilized to micro-machine the trenches. The masking layer 610 can then be removed in order to form a complete silicon part 650 as depicted in FIG. 6C.

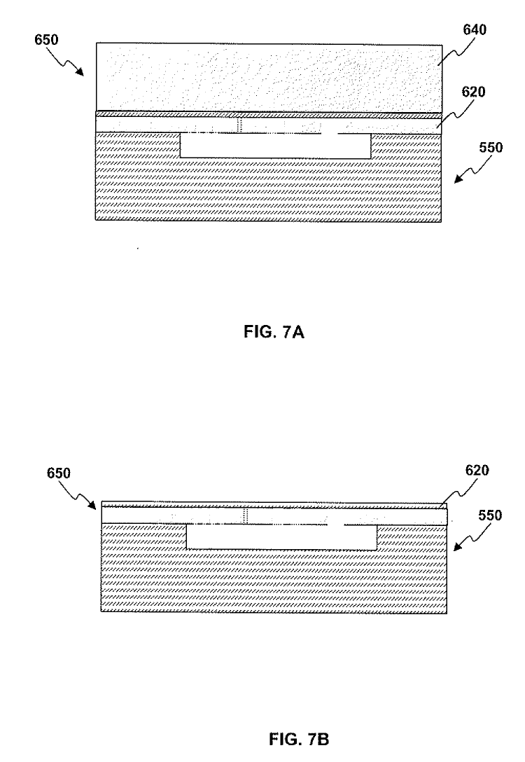

Referring to FIG. 7A, a cross sectional view of the SOI part 650 anodic-bonded onto the top surface of the glass part 550 for the MEMS micro switch is illustrated, in accordance with a preferred embodiment. In anodic-bonding, for example, the device layer 620 of the SOI, part 650 can be bonded to the top surface of the glass part 550.

FIG. 7B illustrates a cross sectional view of the SOI part 650 fusion-bonded onto the top surface of the glass part 550 after removal of the SOI wafer's handle layer 640 for the MEMS micro switch 300. The SOI part 650 and the glass part 550 can be formed into a single piece by anodic bonding. Thereafter, the handle layer 640 located furthest from the device layer 620 can be removed, leaving only the device layer 620 bonded to the top surface of the glass part 550. The handle layer 640 can be removed by methods such as, for example, wet etching, plasma etching and/or grinding. The process can be completed by depositing a metallic structure 710 for electrodes and pads over the device layer 620 of the SOI part 650 as depicted in FIG. 7C.

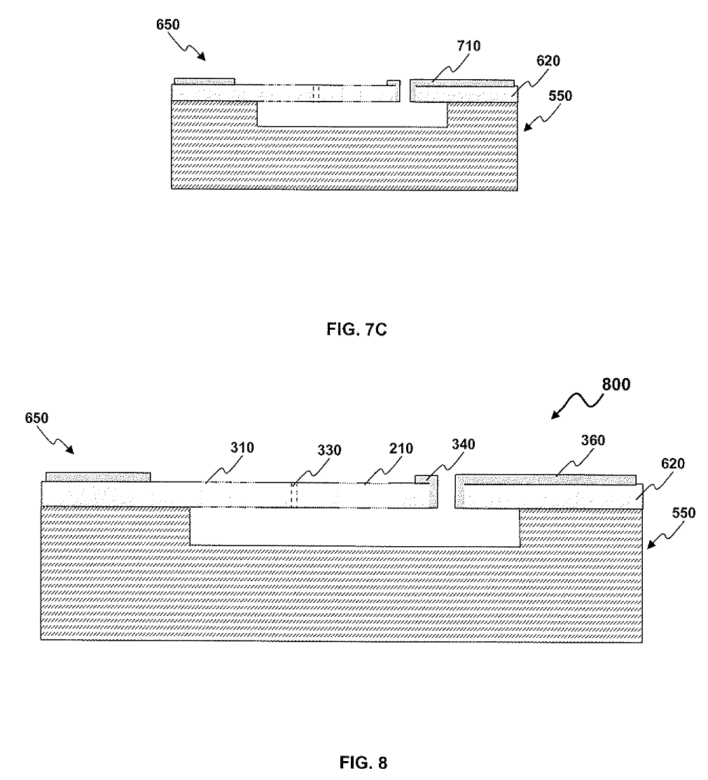

Referring to FIG. 8, another cross sectional view 800 of the SOI part fusion bonded onto the top surface of the glass part after deposition of metallic structures 710 for the MEMS micro switch is illustrated, which can be implemented in accordance with a preferred embodiment. The glass part 550 possesses the same diameter as the SOI part 650, and preferably is 0.5-1 mm thick. As shown in FIG. 8 the device layer 620 includes device structures such as actuator 310, push-pull connector 330, bowed beam 210 and the metallic electrodes 340 and 360.

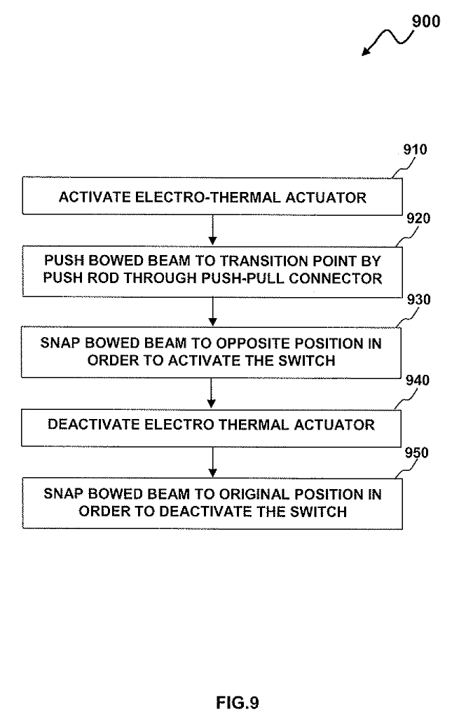

Referring to FIG. 9, a detailed flow chart of operations illustrating logical operational steps of a method 900 for operating MEMS micro switch 300 with snap action is illustrated, in accordance with an alternative embodiment. The electro-thermal actuator 310 can be activated, as depicted at block 910. Thereafter, as indicated at block 920, the bowed beam 210 can be pushed to a transition point by the push rod 320 through the push-pull connector 330. The bowed beam 210 can be snapped to an opposite position in order to activate the switch 300, as shown at block 930. Next, as described at block 940, the electro-thermal actuator 310 can be deactivated. The bowed beam 210 can be snapped to original position in order to deactivate the switch 300, as depicted at block 950.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A MEMS micro switch, comprising:
a lateral bowed beam associated with a push rod, wherein said push rod transits said lateral bowed beam from an original position to a transition point through a push-pull connector by activating an electro-thermal actuator with an actuation current; and
an anchored electrode associated with an electrical contact wherein said electrical contact forms an electrical connection with a movable electrode associated with said push rod when said lateral bowed beam is snapped to an opposite position at said transition point, thereby turning said MEMS micro switch to an “ON” condition with a strong contact force thereon.

2. The MEMS micro switch of claim 1 further comprising:
an SOI wafer;
a glass wafer etched to form a cavity utilizing a patterned masking layer, wherein said glass wafer is associated with said cavity being bonded to said SOI wafer, and wherein said glass wafer provides a final support structure for said MEMS micro switch and said SOI wafer provides a final device structure for said MEMS micro switch.

3. The MEMS micro switch of claim 1 wherein said lateral bowed beam transits back to said original position thereby turning said MEMS micro switch to an “OFF” condition.

4. The MEMS micro switch of claim 2 wherein said final support structure comprises said electro-thermal actuator, said push rod associated with said push-pull connector, said lateral bowed beam and said electrodes.

5. The MEMS micro switch of claim 1 wherein said electro-thermal actuator is sufficiently deflected upon heating by said actuation current in order to establish an electrical connection between said fixed electrode and said movable electrode.

6. The MEMS micro switch of claim 2 wherein said SOI wafer is etched in order to form said final support structure utilizing a silicon DRIE process and said patterned masking layer.

7. The MEMS micro switch of claim 1 further comprising:
an SOI wafer;
a glass wafer etched to form a cavity utilizing a patterned masking layer, wherein said glass wafer is associated with said cavity being bonded to said SOI wafer, and wherein said glass wafer provides a final support structure for said MEMS micro switch and said SOI wafer provides a final device structure for said MEMS micro switch, wherein said lateral bowed beam transits back to said original position thereby turning said MEMS micro switch to an “OFF” condition.

8. A MEMS micro switch, comprising:
a lateral bowed beam associated with a push rod, wherein said push rod transits said lateral bowed beam from an original position to a transition point through a push-pull connector by activating an electro-thermal actuator with an actuation current;
an anchored electrode associated with an electrical contact wherein said electrical contact forms an electrical connection with a movable electrode associated with said push rod when said lateral bowed beam is snapped to an opposite position at said transition point, thereby turning said MEMS micro switch to an “ON” condition with a strong contact force thereon;
an SOI wafer; and
a glass wafer etched to form a cavity utilizing a patterned masking layer, wherein said glass wafer is associated with said cavity being bonded to said SOI wafer, and wherein said glass wafer provides a final support structure for said MEMS micro switch and said SOI wafer provides a final device structure for said MEMS micro switch.

9. The MEMS micro switch of claim 8 wherein said lateral bowed beam transits back to said original position thereby turning said MEMS micro switch to an “OFF” condition.

10. The MEMS micro switch of claim 8 wherein said final support structure comprises said electro-thermal actuator, said push rod associated with said push-pull connector, said lateral bowed beam and said electrodes.

11. The MEMS micro switch of claim 8 wherein said electro-thermal actuator is sufficiently deflected upon heating by said actuation current in order to establish an electrical connection between said fixed electrode and said movable electrode.

12. The MEMS micro switch of claim 8 wherein said SOI wafer is etched in order to form said final support structure utilizing a silicon DRIE process and said patterned masking layer.

13. The MEMS micro switch of claim 8 wherein:
said electro-thermal actuator is sufficiently deflected upon heating by said actuation current in order to establish an electrical connection between said fixed electrode and said movable electrode; and
said SOI wafer is etched in order to form said final support structure utilizing a silicon DRIE process and said patterned masking layer.

14. A method of providing a MEMS micro switch, comprising:
providing a push rod;
associating a lateral bowed beam associated with said push rod, wherein said push rod transits said lateral bowed beam from an original position to a transition point through a push-pull connector by activating an electro-thermal actuator with an actuation current; and
connecting an anchored electrode associated to an electrical contact wherein said electrical contact forms an electrical connection with a movable electrode associated with said push rod when said lateral bowed beam is snapped to an opposite position at said transition point, thereby turning said MEMS micro switch to an “ON” condition with a strong contact force thereon.

15. The method of claim 14 further comprising:
providing an SOI wafer; and
etching a glass wafer to form a cavity utilizing a patterned masking layer, wherein said glass wafer is associated with said cavity being bonded to said SOI wafer, and wherein said glass wafer provides a final support structure for said MEMS micro switch and said SOI wafer provides a final device structure for said MEMS micro switch.

16. The method of claim 14 wherein said lateral bowed beam transits back to said original position thereby turning said MEMS micro switch to an “OFF” condition.

17. The method of claim 15 wherein said final support structure comprises said electro-thermal actuator, said push rod associated with said push-pull connector, said lateral bowed beam and said electrodes.

18. The method of claim 14 wherein said electro-thermal actuator is sufficiently deflected upon heating by said actuation current in order to establish an electrical connection between said fixed electrode and said movable electrode.

19. The method of claim 15 further comprising etching said SOI wafer in order to form said final support structure utilizing a silicon DRIE process and said patterned masking layer.

20. The method of claim 16 further comprising:
configuring said MEMS micro switch such that said push rod pushes or pulls said lateral bowed beam through said push-pull connector even though said push rod and said lateral bowed beam are physically separated from one another, whereby said push rod and said electro-thermal actuator are unaffected by said push rod during said “ON” condition or said “OFF” condition.
